(19) United States
(12) Patent Application Publication
(10) Pub. No.: US 2024/0170625 A1
(43) Pub. Date: May 23, 2024

(54) Display Systems Having Vertical Light-Emitting Diodes

(71) Applicant: Apple Inc., Cupertino, CA (US)

(72) Inventors: Saijin Liu, San Jose, CA (US); Tongbi T Jiang, Santa Clara, CA (US); Rong Liu, Sunnyvale, CA (US)

(21) Appl. No.: 18/551,985

(22) PCT Filed: Mar. 7, 2022
(86) PCT No.: PCT/US2022/019081

§ 371 Date: Sep. 22, 2023

Related U.S. Application Data
(60) Provisional application No. 63/172,026, filed on Apr. 7, 2021.

(51) Int. Cl. H01L 33/58; H01L 25/16

(52) U.S. Cl. CPC H01L 33/58; H01L 25/167

(57) ABSTRACT

An electronic device may include a display having an array of light-emitting diodes mounted to a driver die with driver circuitry for controlling the light-emitting diodes. The diodes may include contact pads. Contact pads for one of the diode terminals (e.g., the anodes or the cathodes) may be individually addressable, whereas the other diode terminals may share a common contact pad. The individually addressable contact pads and the common contact pad may be vertically stacked to improve thermal dissipation. The common contact pad may be interposed between the driver die and the individually addressable contact pads. Alternatively, the individually addressable contact pads may be interposed between the driver die and the common contact pad. Each LED array may have a dedicated driver die or one driver die may be shared between multiple LED arrays. A single LED array may include LEDs of multiple different colors.

This application claims priority to U.S. provisional patent application No. 63/172,026, filed Apr. 7, 2021, which is hereby incorporated by reference herein in its entirety.

### BACKGROUND

This relates generally to electronic devices and, more particularly, to electronic devices with displays.

If care is not taken, the components used in displaying content may be bulky and may not exhibit desired levels of optical performance and power consumption.

### SUMMARY

An electronic device may have one or more displays that produce images for a user.

The display may include a display module that generates light and an optical system that redirects the light from the display module. The display module may include an illumination engine and a spatial light modulator such as a reflective display panel. The illumination engine may include an array of light-emitting diodes mounted to a semiconductor die with driver circuitry. The driver circuitry may independently drive each of the light-emitting diodes in the array using drive signals.

Each light-emitting diode in the array may include a plurality of independently addressable contact pads that are electrically connected to one of the diode terminals (e.g., either the anodes or cathodes) of the light-emitting diodes and a common contact pad that is electrically connected to the other diode terminals of the light-emitting diode. Effectively, the LED array may include independently addressable cathodes and a common anode or independently addressable anodes and a common cathode.

The common contact pad may be interposed between the driver die and the individually addressable contact pads. Alternatively, the individually addressable contact pads may be interposed between the driver die and the common contact pad. In other words, the individually addressable contact pads and the common contact pad may be vertically stacked to improve thermal dissipation.

Each LED array in the illumination engine may have a dedicated driver die or one driver die may be shared between multiple LED arrays. Each LED array may emit a single respective color of light or a single LED array may include LEDs of multiple different colors.

### BRIEF DESCRIPTION OF THE DRAWINGS

FIG. 1 is a diagram of an illustrative system having a display in accordance with some embodiments.

FIG. 2 is a top view of an illustrative display module having an illumination engine and a reflective display panel in accordance with some embodiments.

FIG. 3 is a side view of an illustrative light-emitting diode (LED) array having light-emitting diodes mounted to a driver die in accordance with some embodiments.

FIGS. 4A-4C are cross-sectional side views of an illustrative LED array during various manufacturing steps, where the LED array includes a common electrode interposed between a driver die and individually addressable electrodes for the LEDs in accordance with some embodiments.

FIG. 5 is a top view of an illustrative LED array that includes a common electrode interposed between a driver die and individually addressable electrodes such as the LED array of FIG. 4C in accordance with some embodiments.

FIGS. 6A-6C are cross-sectional side views of an illustrative LED array during various manufacturing steps, where the LED array includes individually addressable electrodes interposed between a driver die and a common electrode for the LEDs in accordance with some embodiments.

FIG. 7 is a top view of an illustrative LED array that includes individually addressable electrodes interposed between a driver die and a common electrode such as the LED array of FIG. 6C in accordance with some embodiments.

FIG. 8 is a diagram of an illustrative illumination engine with multiple LED arrays for different respective wavelengths of light that each include a respective driver die in accordance with some embodiments.

FIG. 9 is a diagram of an illustrative illumination engine with multiple LED arrays for different respective wavelengths of light that are driven by a single driver die in accordance with some embodiments.

FIG. 10A is a side view of an illustrative LED array that is formed on a dummy substrate and electrically connected to driver circuitry using a flexible printed circuit board in accordance with some embodiments.

FIG. 10B is a top view of an illustrative LED array that is formed on a dummy substrate and electrically connected to driver circuitry using a flexible printed circuit board in accordance with some embodiments.

FIG. 11 is a top view of an illustrative LED array that includes LEDs of multiple colors that share a common electrode in accordance with some embodiments.

FIG. 12 is a diagram of an illustrative illumination engine that includes a multi-color LED array of the type shown in FIG. 11 in accordance with some embodiments.

### DETAILED DESCRIPTION

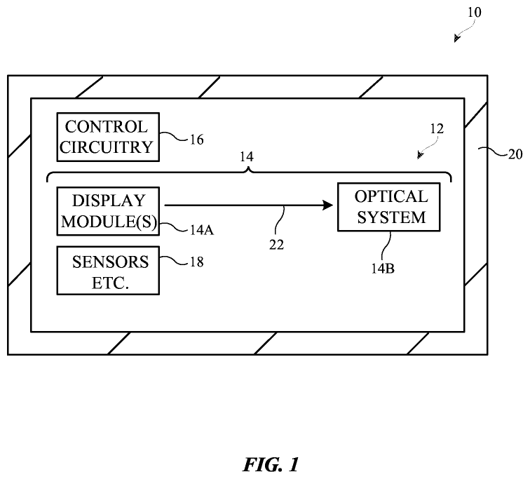

An illustrative system having a device with one or more display systems is shown in FIG. 1. System 10 may be a device having one or more displays such as displays 14 mounted within support structure (housing) 20. System 10 may be a portable device such as a handheld device or laptop computer, a head-mounted device, or other electrical equipment. Displays 14 may include one or more display modules such as display modules 14A and one or more optical systems such as optical systems 14B. Display modules 14A may be mounted in a support structure such as support structure 20. Each display module 14A may emit light 22 (image light) that is redirected using an associated one of optical systems 14B.

The operation of system 10 may be controlled using control circuitry 16. Control circuitry 16 may include storage and processing circuitry for controlling the operation of system 10. Circuitry 16 may include storage such as hard disk drive storage, nonvolatile memory (e.g., electrically-programmable-read-only memory configured to form a solid state drive), volatile memory (e.g., static or dynamic random-access-memory), etc. Processing circuitry in control circuitry 16 may be based on one or more microprocessors, microcontrollers, digital signal processors, baseband processors, power management units, audio chips, graphics processing units, application specific integrated circuits, and other integrated circuits. Software code (instructions) may be stored on storage in circuitry 16 and run on processing circuitry in circuitry 16 to implement operations for system 10 (e.g., data gathering operations, operations involving the adjustment of components using control signals, image rendering operations to produce image content to be displayed for a user, etc.).

System 10 may include input-output circuitry such as input-output devices 12. Input-output devices 12 may be used to allow data to be received by system 10 from external equipment (e.g., a tethered computer, a portable device such as a handheld device or laptop computer, or other electrical equipment) and to allow a user to provide device 10 with user input. Input-output devices 12 may also be used to gather information on the environment in which system 10 is operating. Output components in devices 12 may allow system 10 to provide a user with output and may be used to communicate with external electrical equipment. Input-output devices 12 may include sensors and other components 18 (e.g., image sensors for gathering images of real-world object that are digitally merged with virtual objects on a display in system 10, accelerometers, depth sensors, light sensors, haptic output devices, speakers, batteries, wireless communications circuits for communicating between system 10 and external electronic equipment, etc.). In one suitable arrangement that is sometimes described herein as an example, components 18 may include gaze tracking sensors. As an example, the gaze tracking sensors may include infrared or other light emitters that emit infrared light and image sensors that sense the infrared or other light reflected off of the user's eye (e.g., where the sensed light identifies the gaze direction of the user's eye).

Display modules 14A may include reflective displays (e.g., liquid crystal on silicon (LCOS) displays, digital-micromirror device (DMD) displays, or other spatial light modulators), emissive displays (e.g., micro-light-emitting diode (μLED) displays, organic light-emitting diode (OLED) displays, laser-based displays, etc.), or displays of other types. Light sources in display modules 14A may include μLEDs, OLEDs, LEDs, mini LEDs, lasers, combinations of these, or any other desired light-emitting components. In one suitable arrangement that is described herein as an example, display module 14A may include a spatial light modulator and an illumination engine. The illumination engine may generate illumination light. The spatial light modulator may spatially modulate illumination light to produce image light 22 (e.g., using images to be displayed by the image light). The arrays of light sources in display module 14A may be formed in the illumination engine and may produce the illumination light. The spatial light modulator 33 may be a transmissive or reflective spatial light modulator.

Optical systems 14B may form lenses. If desired, optical system 14B may contain components (e.g., an optical combiner, etc.) to allow real-world image light from real-world images or objects to be combined optically with virtual (computer-generated) images such as virtual images in image light 22. Optical system 14B may include collimating optics. If desired, display module 14A and/or optical system 14B may be mounted within support structure 20 of FIG. 1. Other mounting arrangements may be used, if desired.

System 10 may, if desired, include wireless circuitry and/or other circuitry to support communications with a computer or other external equipment (e.g., a computer that supplies display 14 with image content). During operation, control circuitry 16 may supply image content to display 14. The content may be remotely received (e.g., from a computer or other content source coupled to system 10) and/or may be generated by control circuitry 16 (e.g., text, other computer-generated content, etc.).

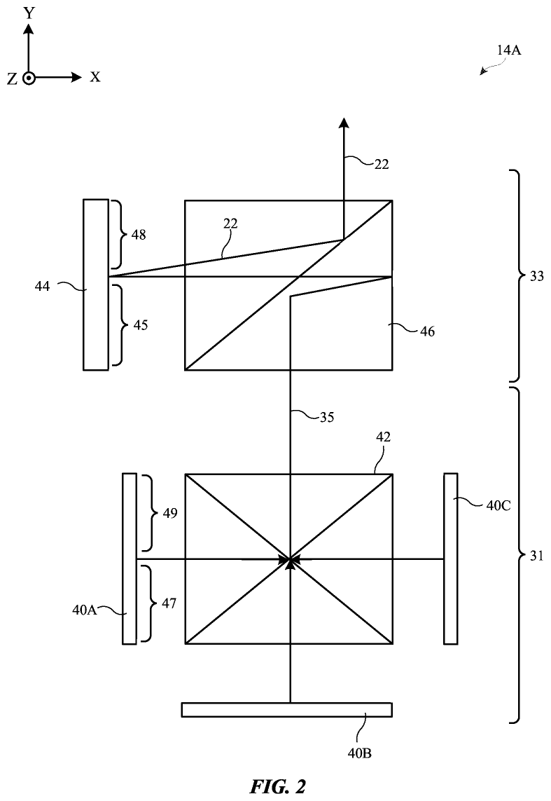

FIG. 2 is a top view of display module 14A with a spatial light modulator 33 and illumination engine 31. In the example of FIG. 2, spatial light modulator 33 is a reflective spatial light modulator. As shown in FIG. 2, illumination engine 31 may include light sources arranged in one or more arrays 40 (sometimes referred to herein as arrays of light sources 40) such as a first array 40A, a second array 40B, and a third array 40C. The light sources in arrays 40 may include any desired light sources (emitters). An example in which the light sources in arrays 40 are light-emitting diodes (LEDs) is described herein as an example. The LEDs may, if desired, include OLEDs, μLEDs, mini LEDs, and/or any other desired light emitting diodes.

Arrays 40A, 40B, and 40C may each emit illumination light 35 of a corresponding wavelength range (e.g., color). For example, array 40A may emit red light, array 40B may emit green light, and array 40C may emit blue light. Prism 42 (sometimes referred to as an optical combiner) may combine the light emitted by arrays 40A, 40B, and 40C into illumination light 35 (e.g., illumination light 35 may include red, green, and blue light, etc.) and may provide illumination light 35 to spatial light modulator 33. Time multiplexing may also be used to provide red, green, and blue illumination light 35 to spatial light modulator 33. Lenses or other optical components may be interposed between arrays 40A, 40B, and/or 40C and prism 42 and/or between prism 42 and spatial light modulator 33.

Spatial light modulator 33 may include prism 46 and a reflective display panel such as display panel 44. Display panel 44 may include a DMD panel, an LCOS panel, or other reflective display panel. Prism 46 may direct illumination light 35 to display panel 44 (e.g., to different pixels on display panel 44). Control circuitry 16 (FIG. 1) controls display panel 44 to selectively reflect illumination light 35 at each pixel location to produce image light 22 (e.g., image light having an image as modulated onto the illumination light by display panel 44). Prism 46 may direct image light 22 to collimating optics of the optical system. The example of FIG. 2 is merely illustrative. Illumination engine 31 may include any desired light sources arranged in any desired manner for providing illumination light 35 of any desired wavelengths to spatial light modulator 33. Illumination engine 31 may only include one or two of arrays 40A, 40B, and 40C or more than three arrays 40 if desired.

If desired, the light sources (e.g., LEDs) in arrays 40A, 40B, and 40C may be independently adjusted (e.g., by control circuitry 16 of FIG. 1) to adjust the spatial distribution of illumination light 35 on reflective display panel 44. Consider an example where region 48 of display 44 is configured to be dark (i.e., dim, off, close to minimum brightness, etc.) and region 45 of display 44 is configured to be bright (i.e., close to maximum brightness). If the light sources in array 40A were controlled in unison, the light sources would need to be close to maximum brightness to meet the brightness demands of region 45 of display 44. However, because the light sources are independently adjustable, the light sources in portion 49 of array 40A (corresponding to dim region 48 of display 44) may be turned off or to a low brightness level while the light sources in portion 47 of array 40A (corresponding to bright region 45 of display 44) may be turned on to a maximum or near-maximum brightness level.

In this way, control circuitry 16 may independently control the intensity, the emission duration, and/or duty cycles of light sources in arrays 40A, 40B, and 40C to control the brightness of illumination light 35 at different regions of display panel 44. For example, control circuitry 16 may independently control the intensity of the light sources in array portion 49 to control the amount of illumination light 35 provided to the pixels in region 48 of display panel 44. Similarly, control circuitry 16 may independently control the intensity, the emission duration, and/or duty cycles of the light sources in array portion 47 to control the amount of illumination light 35 provided to the pixels in region 45 of display panel 44. In this way, the brightness of different regions in the images of image light 22 may be independently controlled.

Including independently adjustable light sources in each array of illumination engine 31 may, for example, conserve power in display module 14A and provide a high quality image with enhanced dynamic range and contrast with locally-dimmed regions.

In general, each array may have any desired number of independently controllable light sources (e.g., every light source in each array may be independently controlled or groups of light sources in each array may be independently controlled). Arrays 40A, 40B, and 40C may be independently controlled (e.g., in addition to independently controlling different light sources within the arrays). In this way, display module 14A may perform local dimming of illumination light 35 and thus the images in image light 22 for any desired number of regions in the image, for regions of any desired size (e.g., for regions as small as one pixel), and in any desired color channels. This flexibility may serve to optimize the appearance of the images in image light 22 regardless of the contents of the images, while also optimizing consumption of resources in display module 14A, for example.

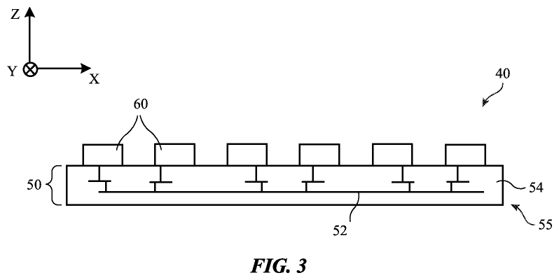

FIG. 3 is a cross-sectional side view of an illustrative light source array for the illumination engine showing how a plurality of light sources may be formed on a substrate that includes driver circuitry. As shown, light sources 60 are formed on substrate 54. Substrate 54 may be a semiconductor substrate formed from a semiconductor material such as silicon (or any other desired material).

Substrate 54 may include driving circuitry 50 that drives the light sources 60 in array 40. Driver circuitry 50 may, for example, produce drive signals and power supply signals that are provided to the light sources in array 40 over conductive interconnect structures (paths) 52. The drive signals may be used to independently control each of the LEDs (or sets of the LEDs) in array 40. The same driver circuitry 50 may be used to drive each array 40 in illumination engine 31 or each array 40 in illumination engine 31 may be driven by respective driver circuitry 50.

Substrate 54 with integral driving circuitry 50 may sometimes be referred to as a driver 55, silicon driver 55, silicon driver die 55, semiconductor driver 55, semiconductor driver die 55, driver die 55, etc.

In one suitable arrangement that is described herein as an example, light sources 60 are LEDs (e.g., OLEDs, μLEDs, mini LEDs, other types of light-emitting diodes, etc.). Light sources 60 may therefore sometimes be referred to herein as LEDs 60. Each LED 60 in array 40 is mounted to the same surface of a substrate layer such as substrate layer 54. LEDs 60 may be arranged in a grid of rows and columns or in any other desired pattern on substrate layer 54.

Each LED 60 may include an anode formed by a p-type semiconductor layer and a cathode formed by an n-type semiconductor layer. In one possible arrangement, each LED may have first and second contact pads (e.g., for the anode and cathode, respectively) formed side-by-side on the substrate 54. The first and second contact pads may be controlled by driver circuitry 50. However, having side-by-side contact pads in this manner may limit the thermal performance of the array. Due to manufacturing tolerance (e.g., minimum gaps between the contact pads) required to avoid undesirably shorting adjacent contact pads, the contact pads may occupy less than 50% of the total surface area of the LED (e.g., when viewed from above in the negative Z-direction in FIG. 3). These contact pads may be the primary path for thermal dissipation of heat generated by the LED. Having a contact pad fill factor of less than 50% therefore limits the thermal performance of the display. Additionally, side-by-side electrodes may require a via through the LED for one of the contact pads. This may cause non-uniform light to be emitted from the LED (e.g., there may be a dark patch overlapping the location of the via).

To improve the thermal performance of the LED and uniformity of light emitted from the LED, each LED may have vertically stacked anode and cathode contact pads. With this type of arrangement, the anode and cathode contact pads may have approximately the same footprint (occupying a high percentage of the total LED surface area). This improves thermal dissipation and, accordingly, the overall performance of array 40. Additionally, having an LED with a vertically stacked anode and cathode contact pads (sometimes referred to as a vertical LED) improves uniformity of light emitted from the LED (since the via through the LED in the side-by-side arrangement can be omitted).

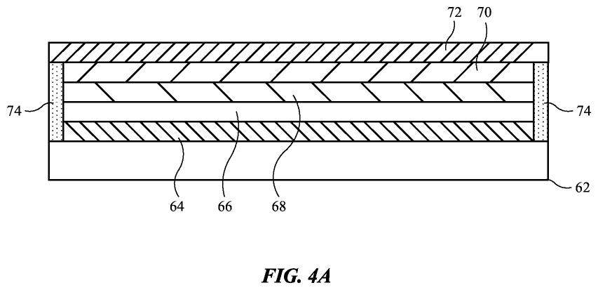

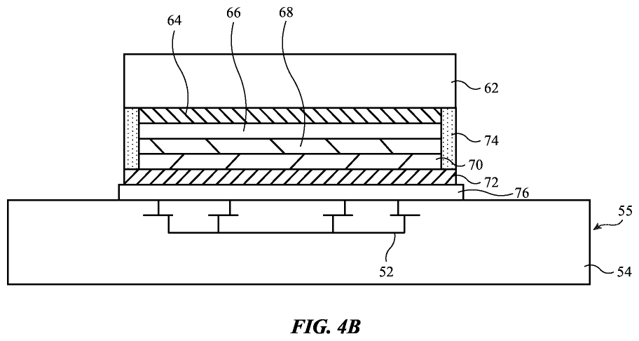

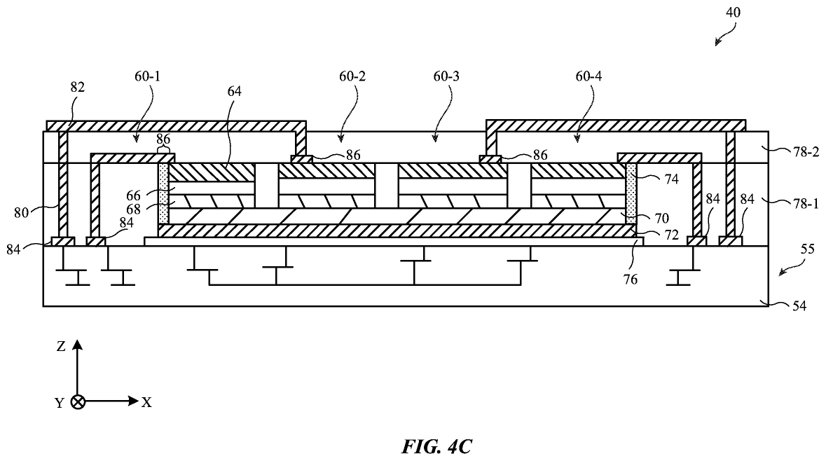

FIGS. 4A-4C show an illustrative method for forming an array 40 with vertical LEDs. First, as shown in FIG. 4A, epitaxial layers may be grown on a substrate. Substrate 62 for the LEDs may sometimes be referred to as LED substrate 62, substrate layer 62, dielectric substrate 62, layer 62, dielectric layer 62, carrier 62, carrier layer 62, dielectric carrier 62, dielectric carrier layer 62, etc. LED substrate 62 may be formed from sapphire, gallium nitride (GaN), gallium arsenic (GaAs), silicon, or any other desired semiconductor and dielectric materials. In one illustrative example, the LED substrate may be formed from sapphire for blue and green LEDs and may be formed from gallium arsenic for red LEDs.

Additional semiconductor layers may be formed on the LED substrate. As shown in FIG. 4A, one or more n-type semiconductor layer(s) 64 is formed on LED substrate 62. The n-type semiconductor layer(s) may include materials such as n-type doped gallium nitride (GaN), n-type aluminum gallium indium phosphide (AlGaInP), etc. The n-type semiconductor layer(s) 64 may be an epitaxial layer (e.g., formed using epitaxy-type crystal growth/material deposition). N-type semiconductor layer(s) 64 may sometimes be referred to herein as n-type epitaxial layer(s) 64, n-type layer(s) 64, etc.

N-type semiconductor layer(s) 64 may ultimately serve as cathodes for the LEDs in array 40. The LED also includes one or more p-type semiconductor layer(s) 68 that ultimately serve as anodes for the LEDs in array 40. The p-type semiconductor layer(s) may include p-type doped gallium nitride (GaN) or any other desired material. The p-type semiconductor layer(s) 68 may be an epitaxial layer (e.g., formed using epitaxy-type crystal growth/material deposition). P-type semiconductor layer(s) 68 may sometimes be referred to herein as p-type epitaxial layer(s) 68, p-type layer(s) 68, etc.

Multi-quantum wells (MQW) such as MQW 66 may be formed at the interface between p-type layer 68 and n-type layer 64. MQW 66 ultimately forms the active light emitting area of LEDs 60. The MQW layer may include gallium nitride (GaN), gallium indium nitride (GaInN), aluminum gallium indium phosphide (AlGaInP), or any other desired materials. Multi-quantum wells 66 may sometimes be referred to as multi-quantum wells layer 66.

P-metal layers 70 and contact pad 72 may be formed over layers 64, 66, and 68. P-metal layers 70 may include one or more of a p-type ohmic contact layer, a mirror metal layer, a current spreading layer, etc. On the p-metal layers 70, a contact pad 72 is formed. Contact pad 72 may be configured to bond to a contact pad of a separate semiconductor substrate (e.g., substrate 50 in FIG. 3). Contact pad 72 may be formed from silver, gold, a gold-tin alloy (AuSn), or any other desired material.

After layers 64, 66, and 68 are formed on substrate 62, the layers may be etched or cut into a desired shape having desired dimensions (e.g., the dimensions of the array). This etching step be performed before or after one or more of layers 70 and 72 are deposited. A dielectric layer 74 may be formed at the edges of the diode formed by n-type layer 64, MQW layer 66, and p-type layer 68.

Next, as shown in FIG. 4B, one or more LED dies from FIG. 4A may be bonded to a semiconductor substrate that includes driving circuitry (e.g., a silicon driver wafer). Driver wafer 55 includes a contact pad 76 on an upper surface of the substrate 54. The contact pad 76 on the driver wafer may be bonded to the contact pad 72 of the LED die. The bonding between contact pads 72 and 76 may be achieved using application of heat with a laser to cause reflow/bonding, by adhering the contact pads together with sintering silver, or any other desired technique. The driver wafer 55 may have a larger footprint than the LED die and may therefore be attached to multiple LED dies during manufacturing if desired. The driver wafer may subsequently be singulated into dies by a dicing process.

Next, as shown in FIG. 4C, the LED substrate 62 may be removed (e.g., by grinding, polishing, chemical etching, laser lift off, or any other desired method). After removal of LED substrate 62, an array of LEDs may be formed using photolithography and etching. In other words, the larger LED die in FIG. 4B may be divided into a plurality of discrete LEDs arranged in an array.

In the example of FIG. 4C, four different LEDs (LED 60-1, LED 60-2, LED 60-3, and LED 60-4) are present after the etching process. The LEDs emit light in the positive Z-direction in FIG. 4C. As shown, each LED still has the same arrangement of components. In other words, each one of LEDs 60-1, 60-2, 60-3, and 60-4 have a MQW layer 66 interposed between an n-type epitaxial semiconductor layer 64 and a p-type epitaxial semiconductor layer 68. The LEDs share a common anode contact (e.g., on the p-type side of the diode) and have individually controllable cathode contacts (e.g., on the n-type side of the diode).

As shown, even after the etching process, the p-type semiconductor layer of all the LEDs is attached to a common p-metal layer 70, contact pad 72, and contact pad 76. Contact pad 72 serves as the contact pad (sometimes referred to as anode electrode) for all the LEDs in the array. Driver die 55 provides a common anode voltage to all of the LEDs via contact pad 76, contact pad 72, and p-metal layer 70. The cathodes, meanwhile, are individually controllable. Driver die 55 may individually control the voltage applied to the n-type semiconductor layer of each LED. Having one shared electrode (e.g., a common anode in FIG. 4C) allows for the LED to be vertically stacked, increasing thermal and optical performance as previously discussed.

A dielectric layer 78-1 is formed to fill the spaces between adjacent LEDs and around the edges of the array. The LEDs may each be laterally surrounded (e.g., in the XY-plane) by portions of dielectric layer 78-1. Respective portions of dielectric layer 78-1 may be interposed between adjacent LEDs 60-1 and 60-2, between adjacent LEDs 60-2 and 60-3, and between adjacent LEDs 60-3 and 60-4.

Vias 80 (sometimes referred to as conductive vias 80, metal vias 80, etc.) and metal interconnect routing lines 82 (sometimes referred to as conductive interconnect routing lines 82, signal lines 82, etc.) may electrically connect contact pads 84 on driver die 55 (sometimes referred to as driver pads 84) to contact pads 86 on n-type semiconductor layers 64 (sometimes referred to as LED contact pads 86, electrode pads 86, etc.). Contact pads 72, 76, 84, and 86 as well as signal lines 82 and vias 80 may all be formed from a conductive material such as a metal material.

Contact pads 86 are used to provide a signal to n-type semiconductor layer 64 and therefore may sometimes be referred to as n contact pads, n-type contact pads, n-terminal contact pads, etc. Contact pad 72 is used to provide a signal to p-type semiconductor layer 68 and therefore may sometimes be referred to as p contact pad, p-type contact pad, p-terminal contact pad, etc.

In some arrangements, all the metal interconnect routing lines 82 may be formed on the upper surface of dielectric layer 78-1. However, this may cause crowding of the routing lines as there is a limited surface area on the upper surface of dielectric layer 78-1 on which to route lines between all the LEDs and the periphery of the array (where the routing lines are connected to driver pads 84 by vias). To alleviate crowding of the routing lines, an additional dielectric layer 78-2 may be included over dielectric layer 78-1. Some of the metal interconnect routing lines 82 (sometimes referred to as signal lines 82) may be routed on the upper surface of dielectric layer 78-2 while some of the metal interconnect routing lines 82 may be routed on the upper surface of dielectric layer 78-1. In this type of arrangement, a signal line for a first LED (e.g., on dielectric layer 78-2) may directly overlap a signal line for a second, different LED (e.g., on dielectric layer 78-1). This type of arrangement increases the amount of surface area available for routing, which alleviates crowding of the signal lines.

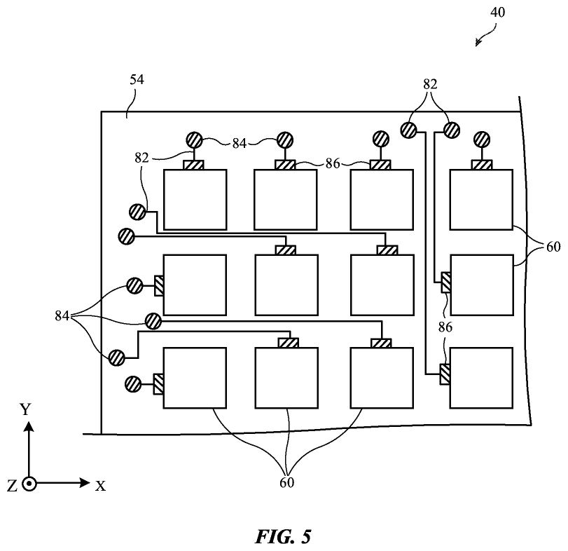

FIG. 5 is a top view of an illustrative LED array that includes vertical LEDs with a common anode. As shown, each LED has a respective n contact pad 86 (that is in electrical contact with the n-type semiconductor layer for that LED, as shown in FIG. 4C). The contact pad 86 for each LED is electrically connected to a driver contact pad 84 by a respective signal line 82 (and via 84). Although not explicitly shown in FIG. 5 due to the top-down view of the array, a via 84 may electrically connect the signal line 82 (e.g., on one of dielectric layers 78-1 or 78-2 in FIG. 4C) to a respective driver contact pad 84 on the surface of the substrate 54. As shown in FIG. 5, the driver contact pads 84 are all formed at the periphery of array 40. This allows the omission of vias within the actual LED area, increasing the uniformity of light emitted by each LED.

The LED array may include any desired number of LEDs. There may be more than one total LED, more than 2 total LEDs, more than 4 total LEDs, more than 9 total LEDs, more than 16 total LEDs, more than 25 total LEDs, more than 60 total LEDs, more than 64 total LEDs, more than 100 total LEDs, more than 1,000 total LEDs, less than 100 total LEDs, less than 75 total LEDs, etc. The LEDs may be arranged in any desired number of rows and columns (e.g., a square array, a non-square array, etc.).

In the example of FIGS. 4A-4C, an LED array is formed with vertical LEDs that have a common anode and individually controllable cathodes. The common anode is interposed between the driver die and the individually controllable cathodes. This example is merely illustrative. Forming the common electrode adjacent to the driver die (as in FIGS. 4A-4C) allows for each LED 60 to have small dimensions. However, the need to route signal lines between the driver die and the individually controllable electrodes may limit the number of LEDs that may be included in the array at a reasonable cost/manufacturing complexity (due to difficulties in fitting all the routing lines in a large array).

In an alternative arrangement, an LED array may be formed with vertical LEDs that have a common cathode and individually controllable anodes. The individually controllable anodes may be interposed between the driver die and the common cathode. This greatly simplifies the routing scheme for the array. Because the individually controllable anodes are attached directly to the driver die, there is no need to fit routing lines for each individually controllable electrode as in FIGS. 4A-4C. The array may therefore include a large number of LEDs without unreasonable increases to cost and manufacturing complexity. However, the individually controllable anodes may need to be precisely aligned with the driver die to avoid shorting. Therefore, each LED in an array of this type may have a requisite size to ensure proper alignment.

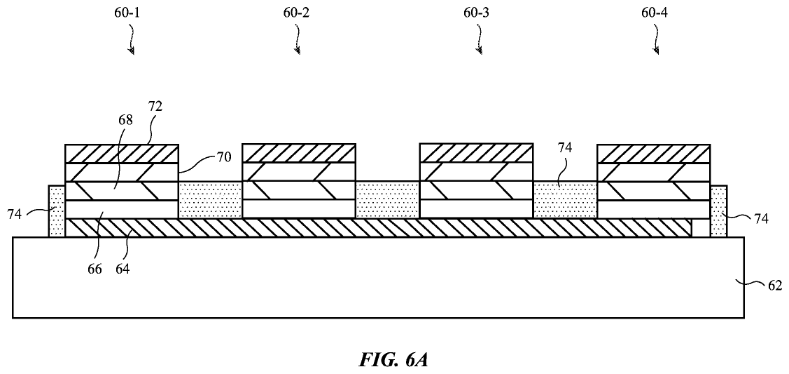

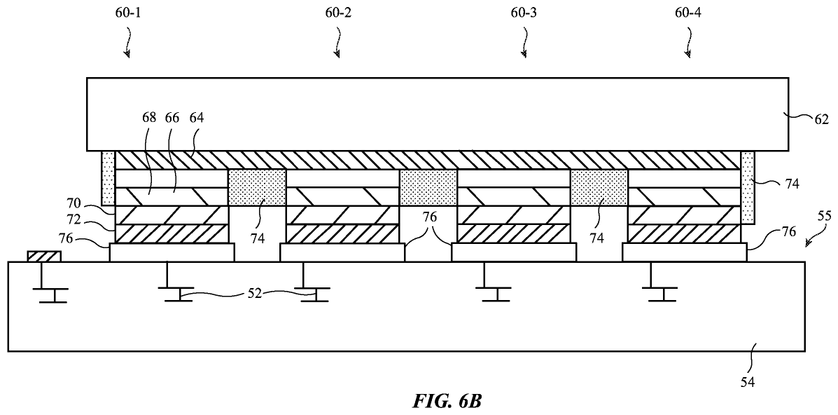

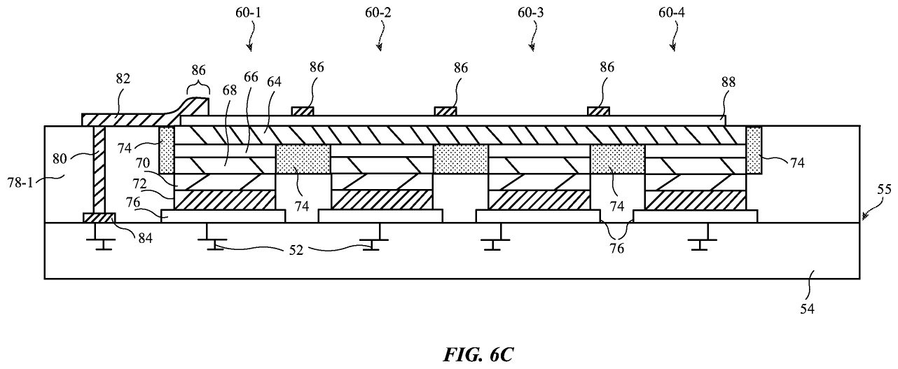

FIGS. 6A-6C show an illustrative method for forming an array 40 with vertical LEDs having a common cathode and individually controllable anodes. Many of the components in FIGS. 6A-6C are similar to as in FIGS. 4A-4C and, for simplicity, the descriptions of these components will not be duplicated in connection with FIGS. 6A-6C.

As shown in FIG. 6A, n-type semiconductor layer 64, MQW layer 66 and p-type semiconductor layer 68 may be formed on LED substrate. After these layers for the LEDs are formed, the LED layers may be etched to form individual diodes. As shown in FIG. 6A, separate light sources 60-1, 60-2, 60-3, and 60-4 are formed by the etching process.

After the etching, dielectric layer 74 is formed around the light sources. Then, p-metal layers 70 and contact pads 72 are formed over each light source. Each light source has a respective p-metal layer 70 and a respective p contact pad 72.

Importantly, the individual diodes in FIG. 6A are formed while the LED semiconductor layers are on LED substrate 62 (e.g., before removal of the LED substrate).

This is in contrast to FIGS. 4A-4C, where the individual diodes are not formed until the LED semiconductor layers are attached to the driver wafer and the LED substrate has been removed.

Next, as shown in FIG. 6B, the LEDs are attached to driver wafer 55. Driver wafer 55 includes contact pads 76 on an upper surface of the substrate 54. Each contact pad 76 on the driver wafer may be bonded to a respective contact pad 72 of an LED 60. The bonding between contact pads 72 and 76 may be achieved using application of heat with a laser to cause reflow/bonding, by adhering the contact pads together with sintering silver, or any other desired technique. The driver wafer 55 may have a larger footprint than the LED die and may therefore be attached to multiple LED dies during manufacturing if desired. The driver wafer may subsequently be singulated into dies by a dicing process.

Next, as shown in FIG. 6C, the LED substrate 62 may be removed (e.g., by grinding, polishing, chemical etching, laser lift off, or any other desired method). A dielectric layer 78-1 is then formed around the periphery of the array. Vias 80 (e.g., that travel through dielectric layer 78-1) and metal interconnect routing lines 82 may electrically connect contact pads 84 on driver die 55 (sometimes referred to as driver pads 84) to contact pads 86 on n-type semiconductor layer 64 (sometimes referred to as LED contact pads 86, electrode pads 86, n contact pads 86, etc.).

The electrode pad 86 may be formed as a continuous mesh (e.g., that overlaps the spaces between adjacent LEDs so as to not overlap the LEDs and decrease transmittance of light). An additional current spreading layer 88 may optionally be formed between the n-type semiconductor layer 64 and electrode pad 86. The current spreading layer 88 may be formed from a conductive material such as indium tin oxide (ITO) and may have a high transparency (e.g., greater than 90%, greater than 95%, greater than 99%, etc.).

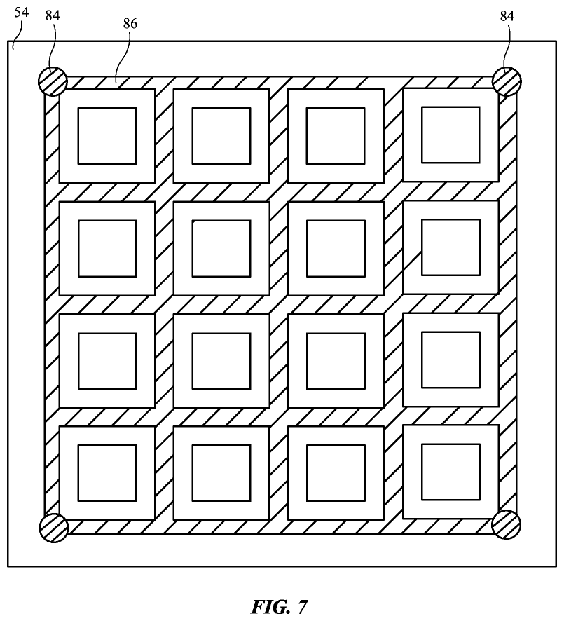

FIG. 7 is a top view of an illustrative LED array that includes vertical LEDs with a common cathode (as in FIGS. 6A-6C). As shown, a metal mesh 86 serves as a contact pad for the cathode. The metal mesh 86 overlaps the areas between each LED. The metal mesh is in electrical contact with the common n-type semiconductor layer 64, as shown in FIG. 6C.

The metal mesh 86 is electrically connected to one or more driver contact pads 84. Although not explicitly shown in FIG. 7 due to the top-down view of the array, a via may electrically connect the metal mesh 86 to one or more driver contact pads 84 on the surface of the substrate 54. As shown in FIG. 7, the driver contact pads 84 are all formed at the periphery of array 40. Even though the metal mesh 86 provides the same voltage to the n-type semiconductor layer 64, the metal mesh may be coupled to multiple driver contact pads to ensure a uniform voltage across the cathode. As shown in FIG. 6C, an additional current spreading layer 88 may also be included in contact with the metal mesh 86.

It should be noted that in either the embodiments of FIGS. 4A-4C and FIG. 5 (with a common anode and individually addressable cathodes) or the embodiments of FIGS. 6A-6C and FIG. 7 (with a common cathode and individually addressable anodes), one or more optical microstructures (e.g., microlenses, photonics lattice, etc.) may be formed over the LEDs.

Additionally, the relative positioning of the cathode and anode are merely illustrative. In general, the positions of the cathode and anode in any given embodiment may be switched. For example, in FIG. 4C, instead of a common anode that is adjacent to the driver die and interposed between the driver die and individually addressable cathodes, there may be a common cathode that is adjacent to the driver die and interposed between the driver die and individually addressable anodes. Similarly, in FIG. 6C, instead of individually addressable anodes that are adjacent to the driver die and interposed between the driver die and a common cathode, there may be individually addressable cathodes that are adjacent to the driver die and interposed between the driver die and a common anode. In general, for each LED array, there may be one common electrode and one plurality of individually addressable electrodes. The common electrode and the plurality of individually addressable electrodes may be vertically overlapping (e.g., overlapping in the direction in which light is emitted by the LED array). The common electrode may be interposed between the driver die and the individually addressable electrodes (as in FIG. 4C) or the individually addressable electrodes may be interposed between the driver die and the common electrode (as in FIG. 6C).

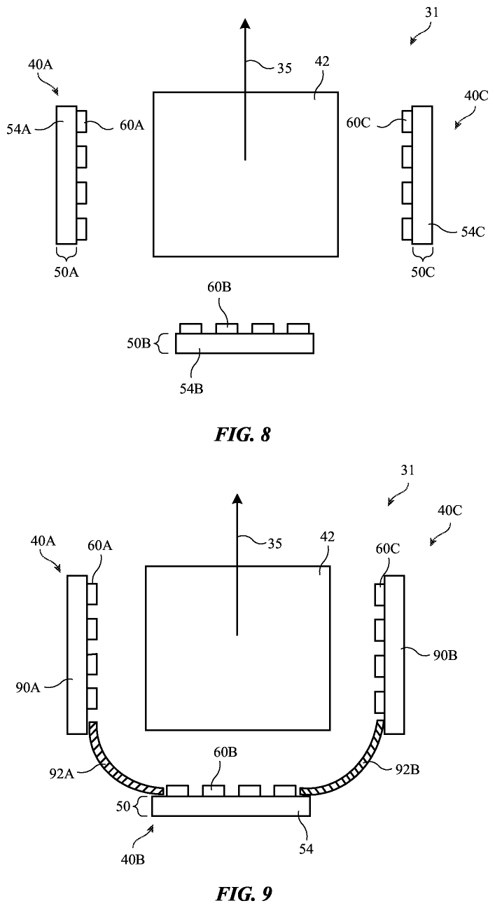

FIGS. 8 and 9 show illumination engines that may include LED arrays of the type shown in FIGS. 4-7. As shown in FIG. 8, the illumination engine 31 may include arrays 40A, 40B, and 40C that each emit illumination light of a corresponding wavelength range (e.g., color). For example, array 40A may emit red light, array 40B may emit green light, and array 40C may emit blue light. Prism 42 (sometimes referred to as an optical combiner) may combine the light emitted by arrays 40A, 40B, and 40C into illumination light 35 (e.g., illumination light 35 may include red, green, and blue light, etc.).

In one possible arrangement, shown in FIG. 8, each LED array includes a respective driver die. In other words, LED array 40A includes a plurality of LEDs 60A on a semiconductor substrate 54A that includes driver circuitry 50A. LED array 40B includes a plurality of LEDs 60B on a semiconductor substrate 54B that includes driver circuitry 50B. LED array 40C includes a plurality of LEDs 60C on a semiconductor substrate 54C that includes driver circuitry 50C.

In another possible arrangement, shown in FIG. 9, a single driver die may control all three LED arrays. As shown in FIG. 9, LED array 40B includes a plurality of LEDs 60B on a semiconductor substrate 54 that includes driver circuitry 50. However, in addition to driving LEDs 60B, the driver circuitry 50 in semiconductor substrate 54 also drives LEDs 60A of array 40A and LEDs 60C of array 40C. In this way, only one driver die is included (instead of three driver dies as in FIG. 8). Sharing a single driver die allows for the omission of two driver dies in the system, which may reduce manufacturing complexity and cost for the system.

Since arrays 40A and 40C do not have a dedicated driver die, the LEDs may be formed on a dummy substrate 90. Array 40A includes LEDs 60A on dummy substrate 90A while array 40C includes LEDs 60C on dummy substrate 90B. The dummy substrate may be formed from glass, silicon, or another desired dielectric material. The dummy substrate does not include driving circuitry. Instead, a flexible printed circuit board (sometimes referred to as flexible printed circuit) connects metal contacts and routing layers on the dummy substrate to driver circuitry 50 in semiconductor substrate 54.

As shown, a first flexible printed circuit board 92A electrically connects driver circuitry 50 in semiconductor substrate 54 (of array 40B) to metal contacts and routing layers on dummy substrate 90A. A second flexible printed circuit board 92B electrically connects driver circuitry 50 in semiconductor substrate 54 to metal contacts and routing layers on dummy substrate 90B. In this way, driver circuitry 50 can drive the LEDs of arrays 40A, 40B, and 40C.

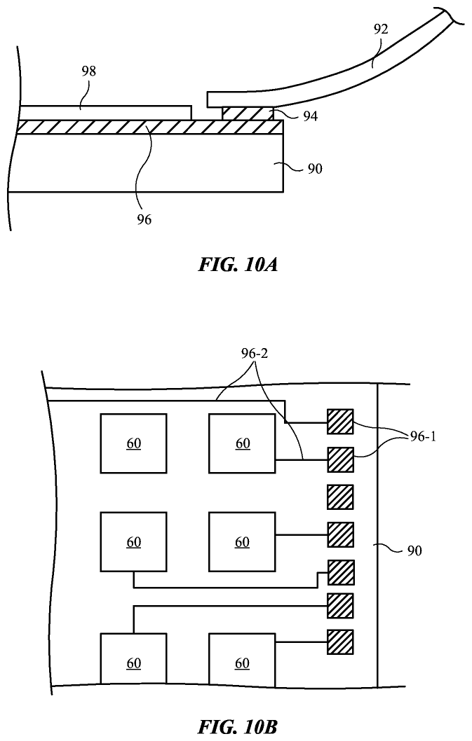

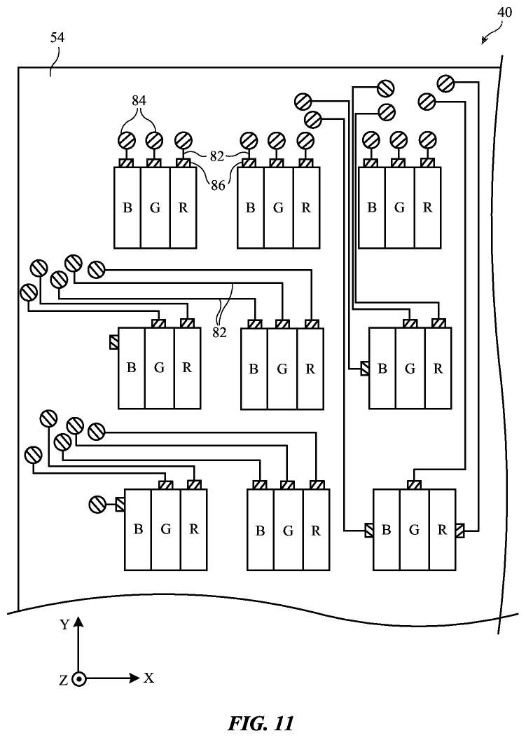

FIG. 10A is a cross-sectional side view of a dummy substrate that is electrically connected to a flexible printed circuit board. As shown in FIG. 10A, metal layer 96 may be formed on dummy substrate 90 (sometimes referred to as substrate 90, dielectric substrate 90, etc.). Metal layer 96 may include contact pads for electrically connecting to corresponding contact pads 94 of flexible printed circuit board 92. Metal layer 96 may also include routing lines for routing signals from the contact pads to corresponding LEDs in the array. A dielectric layer 98 may cover metal layer 96 to protect metal layer 96 from damage. An additional dielectric layer may also optionally be interposed between metal layer 96 and substrate 90. Additional dielectric layers may also be included to allow the routing lines to be distributed across multiple planes (as shown and discussed in connection with FIG. 4C).

FIG. 10B is a top view of a dummy substrate of the type shown in FIG. 10A. As shown, metal layer 96 includes contact pads 96-1. The contact pads may be arranged at the edge of substrate 90 to allow the contact pads to easily electrically connect to the flexible printed circuit board. As shown in FIG. 10B, routing lines 96-2 are also included in the metal layer to electrically connect the contact pads with corresponding LEDs (similar to as shown in FIG. 5, for example).

In the embodiments of FIGS. 8 and 9, there is a dedicated LED array 40 for each desired wavelength of light (e.g., a red LED array, a green LED array, and a blue LED array). However, this example is merely illustrative. In another possible arrangement, shown in FIG. 11, LEDs of multiple colors may be formed on a single substrate.

As shown in FIG. 11, a plurality of light sources 60 of different colors are formed an array. The light sources may be arranged in groups of one red (R), one green (G), and one blue (B) LED. An array of these LED groups is then formed across the semiconductor substrate 54. FIG. 11 shows an example where each LED has an individually addressable cathode and a common anode (e.g., similar to FIGS. 4A-4C and FIG. 5). Accordingly, a similar routing scheme to FIG. 5 is used in FIG. 11, with each LED having a corresponding electrode pad 86 that is electrically connected to a driver pad 84 by a respective routing line 82. An electrode arrangement as in FIGS. 6A-6C (with individually addressable electrodes interposed between the driver die and a common electrode) may also be used for the multi-color array of FIG. 11.

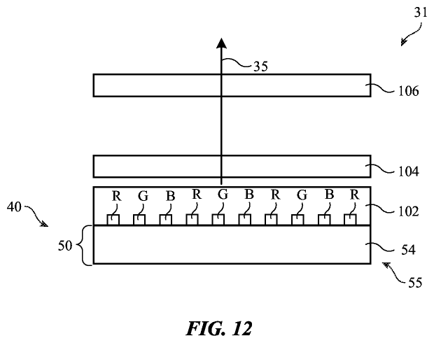

Incorporating multiple colors of LEDs in a single array may allow for the prism (optical combiner) to be omitted from illumination engine 31. FIG. 12 is a cross-sectional side view of an illustrative illumination engine with a multi-color LED array. As shown, red (R), green (G), and blue (B) LEDs are included in the array.

Because multiple colors are emitted from the array, the optical combiner 42 of FIGS. 8 and 9 is omitted in the illumination engine of FIG. 12. The multi-color LED array emits light 35 having multiple desired colors. Encapsulation 102 may be formed over the LEDs. A diffuser layer 104 may be formed over encapsulation 102. The diffuser layer 104 may mix the illumination light 35. A condenser lens 106 may also optionally be included above diffuser layer 104. The condenser lens may focus the illumination light from a divergent beam into a parallel or converging beam.

In accordance with an embodiment, a display system is provided that includes an array of light-emitting diodes configured to emit light in a first direction; and a driver die with driver circuitry that controls the array of light-emitting diodes, the array of light-emitting diodes are mounted on the driver die, each light-emitting diode includes an n-type semiconductor layer and a p-type semiconductor layer, each light-emitting diode includes a respective contact pad for a selected one of the n-type semiconductor layer and a p-type semiconductor layer, the array of light-emitting diodes share a common contact pad for a remaining one of the n-type semiconductor layer and a p-type semiconductor layer, and the common contact pad overlaps the respective contact pads in the first direction.

In accordance with another embodiment, each respective contact pad is electrically connected to the n-type semiconductor layer for that light-emitting diode and the array of light-emitting diodes shares a common contact pad for the p-type semiconductor layer.

In accordance with another embodiment, each respective contact pad is electrically connected to the p-type semiconductor layer for that light-emitting diode and the array of light-emitting diodes shares a common contact pad for the n-type semiconductor layer.

In accordance with another embodiment, the common contact pad is interposed between the driver die and the respective contact pads.

In accordance with another embodiment, the display system includes a first dielectric layer formed over the driver die that has portions that laterally surround the light-emitting diodes in the array.

In accordance with another embodiment, the display system includes conductive routing lines on an upper surface of the first dielectric layer; and conductive vias, the conductive vias and the conductive routing lines electrically connect at least some of the respective contact pads to the driver die.

In accordance with another embodiment, the conductive vias are formed at a periphery of the array of light-emitting diodes.

In accordance with another embodiment, the display includes a second dielectric layer that is formed over the first dielectric layer; additional conductive routing lines on an upper surface of the second dielectric layer; and additional conductive vias that extend through the first and second dielectric layers.

In accordance with another embodiment, at least one of the additional conductive routing lines directly overlaps one of the conductive routing lines in the first direction.

In accordance with another embodiment, the respective contact pads are interposed between the driver die and the common contact pad.

In accordance with another embodiment, the display system includes a current spreading layer that is electrically connected to the common contact pad, the current spreading layer is formed from indium tin oxide.

In accordance with another embodiment, the common contact pad is formed as a mesh over the array of light-emitting diodes.

In accordance with another embodiment, the array of light-emitting diodes has at least a first subset of light-emitting diodes that emits light at a first wavelength and a second subset of light-emitting diodes that emits light at a second wavelength that is different than the first wavelength.

In accordance with an embodiment, a display system is provided that includes a display panel configured to produce image light by modulating illumination light; and an illumination engine configured to generate the illumination light, the illumination engine includes a first array of light-emitting diodes that emit light at a first wavelength, the first array of light-emitting diodes is mounted on a driver die and is controlled by driver circuitry in the driver die; a second array of light-emitting diodes that emit light at a second wavelength that is different than the first wavelength, the second array of light-emitting diodes is mounted on a first substrate and is controlled by the driver circuitry in the driver die; a third array of light-emitting diodes that emit light at a third wavelength that is different than the first and second wavelengths, the third array of light-emitting diodes is mounted on a second substrate and is controlled by the driver circuitry in the driver die; and an optical combiner that is configured to combine the light from the first, second, and third arrays into the illumination light.

In accordance with another embodiment, the illumination engine includes a first flexible printed circuit that electrically connects the second array of light-emitting diodes on the first substrate to the driver circuitry in the driver die.

In accordance with another embodiment, the illumination engine includes a second flexible printed circuit that electrically connects the third array of light-emitting diodes on the second substrate to the driver circuitry in the driver die.

In accordance with another embodiment, the first and second substrates are dummy substrates that do not include driver circuitry.

In accordance with another embodiment, the first and second substrates are glass substrates.

In accordance with an embodiment, a display system is provided that includes an array of light-emitting diodes configured to emit illumination light; and a substrate with driver circuitry that controls the array of light-emitting diodes, the array of light-emitting diodes are mounted on the substrate, each light-emitting diode includes an n-type semiconductor layer and a p-type semiconductor layer, each light-emitting diode includes an respective p contact pad that electrically connects the p-type semiconductor layer for that light-emitting diode to the driver circuitry, the array of light-emitting diodes share a common n contact pad that electrically connects the n-type semiconductor layer for each light-emitting diode to the driver circuitry, and the p contact pads are interposed between the substrate and the n contact pad.

In accordance with another embodiment, each light-emitting diode additionally includes a multi-quantum wells layer that is interposed between the n-type semiconductor layer and the p-type semiconductor layer for that light-emitting diode.

The foregoing is merely illustrative and various modifications can be made to the described embodiments. The foregoing embodiments may be implemented individually or in any combination.

What is claimed is:

1. A display system comprising:
an array of light-emitting diodes configured to emit light in a first direction; and
a driver die with driver circuitry that controls the array of light-emitting diodes, wherein the array of light-emitting diodes are mounted on the driver die, wherein each light-emitting diode comprises an n-type semiconductor layer and a p-type semiconductor layer, wherein each light-emitting diode comprises a respective contact pad for a selected one of the n-type semiconductor layer and a p-type semiconductor layer, wherein the array of light-emitting diodes share a common contact pad for a remaining one of the n-type semiconductor layer and a p-type semiconductor layer, and wherein the common contact pad overlaps the respective contact pads in the first direction.

2. The display system defined in claim 1, wherein each respective contact pad is electrically connected to the n-type semiconductor layer for that light-emitting diode and wherein the array of light-emitting diodes shares a common contact pad for the p-type semiconductor layer.

3. The display system defined in claim 1, wherein each respective contact pad is electrically connected to the p-type semiconductor layer for that light-emitting diode and wherein the array of light-emitting diodes shares a common contact pad for the n-type semiconductor layer.

4. The display system defined in claim 1, wherein the common contact pad is interposed between the driver die and the respective contact pads.

5. The display system defined in claim 4, further comprising:
a first dielectric layer formed over the driver die that has portions that laterally surround the light-emitting diodes in the array.

6. The display system defined in claim 5, further comprising:
conductive routing lines on an upper surface of the first dielectric layer; and
conductive vias, wherein the conductive vias and the conductive routing lines electrically connect at least some of the respective contact pads to the driver die.

7. The display system defined in claim 6, wherein the conductive vias are formed at a periphery of the array of light-emitting diodes.

8. The display system defined in claim 6, further comprising:
a second dielectric layer that is formed over the first dielectric layer;
additional conductive routing lines on an upper surface of the second dielectric layer; and
additional conductive vias that extend through the first and second dielectric layers.

9. The display system defined in claim 8, wherein at least one of the additional conductive routing lines directly overlaps one of the conductive routing lines in the first direction.

10. The display system defined in claim 1, wherein the respective contact pads are interposed between the driver die and the common contact pad.

11. The display system defined in claim 10, further comprising:
a current spreading layer that is electrically connected to the common contact pad, wherein the current spreading layer is formed from indium tin oxide.

12. The display system defined in claim 10, wherein the common contact pad is formed as a mesh over the array of light-emitting diodes.

13. The display system defined in claim 1, wherein the array of light-emitting diodes has at least a first subset of light-emitting diodes that emits light at a first wavelength and a second subset of light-emitting diodes that emits light at a second wavelength that is different than the first wavelength.

14. A display system comprising:
a display panel configured to produce image light by modulating illumination light; and
an illumination engine configured to generate the illumination light, wherein the illumination engine comprises:
a first array of light-emitting diodes that emit light at a first wavelength, wherein the first array of light-emitting diodes is mounted on a driver die and is controlled by driver circuitry in the driver die;
a second array of light-emitting diodes that emit light at a second wavelength that is different than the first wavelength, wherein the second array of light-emitting diodes is mounted on a first substrate and is controlled by the driver circuitry in the driver die;
a third array of light-emitting diodes that emit light at a third wavelength that is different than the first and second wavelengths, wherein the third array of light-emitting diodes is mounted on a second substrate and is controlled by the driver circuitry in the driver die; and
an optical combiner that is configured to combine the light from the first, second, and third arrays into the illumination light.

15. The display system defined in claim 14, wherein the illumination engine further comprises:
a first flexible printed circuit that electrically connects the second array of light-emitting diodes on the first substrate to the driver circuitry in the driver die.

16. The display system defined in claim 14, wherein the illumination engine further comprises:
a second flexible printed circuit that electrically connects the third array of light-emitting diodes on the second substrate to the driver circuitry in the driver die.

17. The display system defined in claim 14, wherein the first and second substrates are dummy substrates that do not include driver circuitry.

18. The display system defined in claim 14, wherein the first and second substrates are glass substrates.

19. A display system comprising:
an array of light-emitting diodes configured to emit illumination light; and
a substrate with driver circuitry that controls the array of light-emitting diodes, wherein the array of light-emitting diodes are mounted on the substrate, wherein each light-emitting diode comprises an n-type semiconductor layer and a p-type semiconductor layer, wherein each light-emitting diode comprises an respective p contact pad that electrically connects the p-type semiconductor layer for that light-emitting diode to the driver circuitry, wherein the array of light-emitting diodes share a common n contact pad that electrically connects the n-type semiconductor layer for each light-emitting diode to the driver circuitry, and wherein the p contact pads are interposed between the substrate and the n contact pad.

20. The display system defined in claim 19, wherein each light-emitting diode additionally includes a multi-quantum wells layer that is interposed between the n-type semiconductor layer and the p-type semiconductor layer for that light-emitting diode.
